(19) United States
(12) Patent Application Publication
(10) Pub. No.: US 2011/0127604 A1
(43) Pub. Date: Jun. 2, 2011

(54) SEMICONDUCTOR DEVICE

(76) Inventor: Ken SATO, Niiza-shi (JP)

(21) Appl. No.: 12/946,902

(22) Filed: Nov. 16, 2010

(30) Foreign Application Priority Data
Nov. 30, 2009 (JP) 2009-271413

(51) Int. Cl. H01L 29/778

(52) U.S. Cl. 257/332; 257/E29.252

(57) ABSTRACT

A semiconductor device having a field plate structure shows a high electric field relaxation effect. The semiconductor device comprises a nitride semiconductor layer formed on a substrate, a source electrode formed so as to electrically contact the nitride semiconductor layer, a drain electrode formed so as to electrically contact the nitride semiconductor layer, a gate electrode formed between the source electrode and the drain electrode on the nitride semiconductor layer, a cap layer formed between the gate electrode and the drain electrode on the surface of the nitride semiconductor layer, a passivation layer covering the cap layer and a field plate formed as part of the gate electrode on the layer formed by the cap layer and the passivation layer, the cap layer being made of a composition containing part of the composition of the material of the nitride semiconductor layer and having a thickness of 2 to 50 nm, the end of the cap layer at the side of the gate electrode being provided with a taper angle of not greater than 60° to form a slope.

### BACKGROUND OF THE INVENTION

1. Field of the Invention

The present invention relates to a semiconductor device and, more particularly, it relates to a semiconductor device having a field plate structure.

2. Description of the Related Art

High electron mobility transistor (HEMT) structures showing a high electron mobility are being popularly employed for electronic devices formed by using a gallium nitride (GaN)-based chemical compound semiconductor.

When a HEMT structure is employed as a power device, a field plate structure is used for an electrode end section for the purpose of uniformizing the electric field intensity distribution and realizing a high withstand voltage. It is believed that the most ideal field plate structure shows a shape of an inclined field plate as shown in FIG. 19 (refer to, e.g., Patent Document 1).

FIG. 19 shows part of the gate electrode section of a HEMT structure. In FIG. 19, reference symbol 100 denotes an AlGaN surface layer of the HEMT structure and reference symbol 101 denotes a passivation layer made of silicon nitride (SiN) or silicon oxide (SiO), while reference symbol 102 denotes a gate electrode. Of the gate electrode 102, the range indicated by arrow F103 shows a field plate 103. In the structure, the passivation layer 101 is provided with a tapered part 104 so that the contact area of the field plate 103 and the passivation layer 101 has a slope 105.

Generally, when an electrode shows an angle, a high electric field concentration occurs around the angle. As for the arrangement of FIG. 19, the angle 106 of the gate electrode 102 is made mild to realize high withstand voltage by providing the field plate 103 with a slope 105 to make it effectively possible to suppress any high electric field concentration.

### CITATION LIST

### Patent Document

[Patent Document 1] Japanese PCT National Publication No. 2007-505501.

The use of wet etching may be conceivable when a passivation layer that is made of SiN or SiO is to be tapered in order to produce a slope on a field plate. However, it is difficult to precisely control a wet etching process. Hence, wet etching is not suited for fine machining. Therefore, highly productive dry etching is more often than not employed for conventional semiconductor processes. However, anisotropic etching is likely to occur when dry etching SiN or SiO. Then, angle φ₀ of a tapered part 108 of a passivation layer 107 is apt to become large as shown in FIG. 20 and a high electric field concentration takes place at an end section 109 of the gate electrode 102 to give rise to a problem of difficulty of achieving an electric field relaxation effect. The use of a multi-step field plate structure for providing a multiple of steps at an end section 111 of the passivation layer 110 in range F113 of the gate electrode 112 as shown in FIG. 21 is being discussed in order to reduce such a problem. But, even when a multi-step structure as shown in FIG. 21 is employed, angle 115 of the first step to which an electric field is maximally applied shows a large angle φ₀′ for a tapered part 114 to by turn give rise to a problem of a low electric field relaxation effect if compared with the slope 105 shown in FIG. 19.

### SUMMARY OF THE INVENTION

The present invention provides a semiconductor device having a field plate structure showing a high electric field relaxation effect.

According to a first aspect of the present invention, the semiconductor device includes:

a nitride semiconductor layer formed on a substrate;

a source electrode formed so as to electrically contact part of the nitride semiconductor layer;

a drain electrode formed so as to electrically contact part of the nitride semiconductor layer;

a gate electrode formed between the source electrode and the drain electrode on the nitride semiconductor layer;

a cap layer formed between the gate electrode and the drain electrode on the surface of the nitride semiconductor layer;

a passivation layer covering the cap layer; and

a field plate formed as part of the gate electrode on the layer formed by the cap layer and the passivation layer;

the cap layer being made of a composition containing part of the composition of the material of the nitride semiconductor layer and having a thickness of 2 to 50 nm;

an end of the cap layer at the side of the gate electrode being provided with a taper angle of not greater than 60° to form a slope.

Thus, the present invention can provide a semiconductor device having a field plate structure showing a high electric field relaxation effect.

### BRIEF DESCRIPTION OF THE DRAWINGS

FIG. 1 is a schematic plan view of a first embodiment of semiconductor device according to the present invention;

FIG. 2 is a schematic cross-sectional view of the first embodiment of semiconductor device according to the present invention;

FIG. 3 is an enlarged cross-sectional view of a part of the first embodiment of semiconductor device according to the present invention;

FIGS. 4A to 4D are schematic cross-sectional view of the first embodiment of semiconductor device according to the present invention, showing the steps down to forming a filed plate;

FIGS. 5A and 5B are schematic cross-sectional view of the first embodiment of semiconductor device according to the present invention, showing the steps down to forming a filed plate;

FIGS. 6A to 6C are schematic cross-sectional view of a modified example of the first embodiment of semiconductor device according to the present invention, showing the steps down to forming a filed plate;

FIGS. 7A to 7D are schematic cross-sectional view of a modified example of the first embodiment of semiconductor device according to the present invention, showing the steps down to forming a filed plate;

FIG. 8 is an enlarged cross-sectional view of a part of a second embodiment of semiconductor device according to the present invention;

FIGS. 9A to 9D are schematic cross-sectional view of the second embodiment of semiconductor device according to the present invention, showing the steps down to forming a filed plate;

FIGS. 10A to 10C are schematic cross-sectional view of the second embodiment of semiconductor device according to the present invention, showing the steps down to forming a filed plate;

FIGS. 11A to 11D are schematic cross-sectional view of a modified example of the second embodiment of semiconductor device according to the present invention, showing the steps down to forming a filed plate;

FIG. 12 is an enlarged cross-sectional view of a part of a third embodiment of semiconductor device according to the present invention;

FIGS. 13A to 13D are schematic cross-sectional view of the third embodiment of semiconductor device according to the present invention, showing the steps down to forming a filed plate;

FIGS. 14A and 14B are schematic cross-sectional view of the third embodiment of semiconductor device according to the present invention, showing the steps down to forming a filed plate;

FIGS. 15A to 15E are schematic cross-sectional view of a modified example of the third embodiment of semiconductor device according to the present invention, showing the steps down to forming a filed plate;

FIG. 16 is an enlarged cross-sectional view of a part of a fourth embodiment of semiconductor device according to the present invention;

FIGS. 17A to 17D are schematic cross-sectional view of the fourth embodiment of semiconductor device according to the present invention, showing the steps down to forming a filed plate;

FIGS. 18A to 18C are schematic cross-sectional view of the fourth embodiment of semiconductor device according to the present invention, showing the steps down to forming a filed plate;

FIG. 19 is an enlarged cross-sectional view of a part of a known semiconductor device;

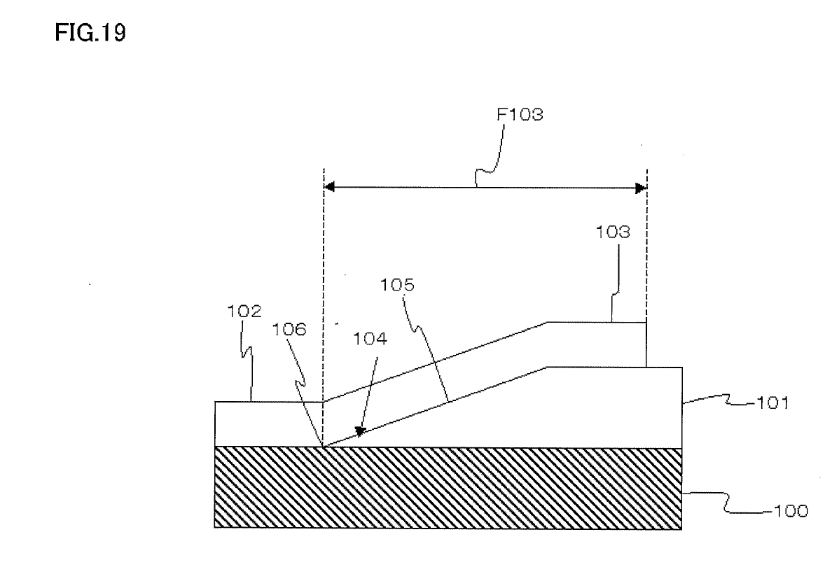

FIG. 20 is an enlarged cross-sectional view of a part of a known semiconductor device; and

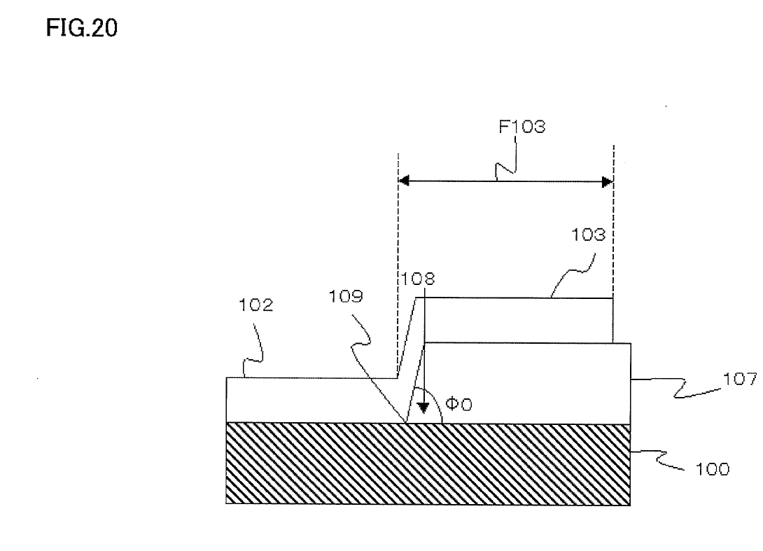

FIG. 21 is an enlarged cross-sectional view of a part of a known semiconductor device.

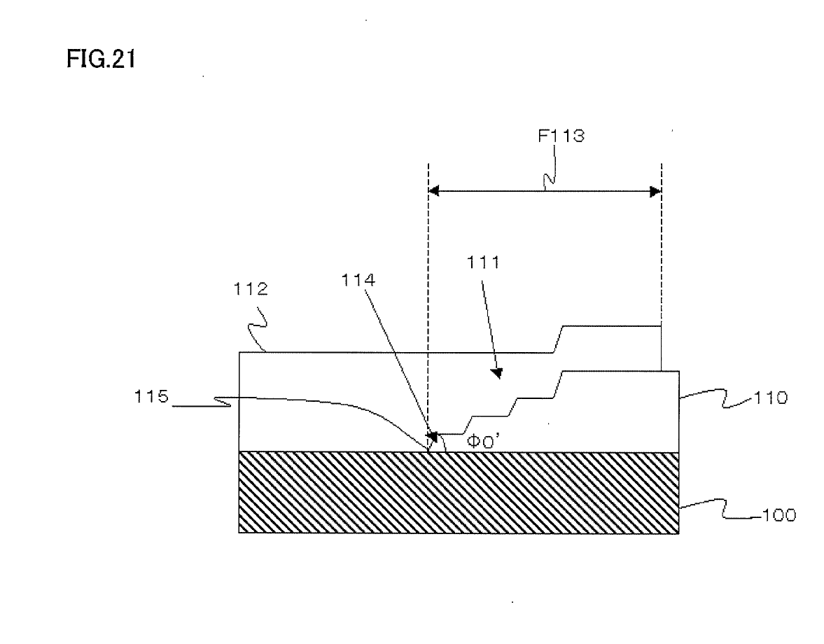

### DESCRIPTION OF THE PREFERRED EMBODIMENTS

Now, the present invention will be described in greater detail by referring to the accompanying drawings that illustrate preferred embodiments of the invention.

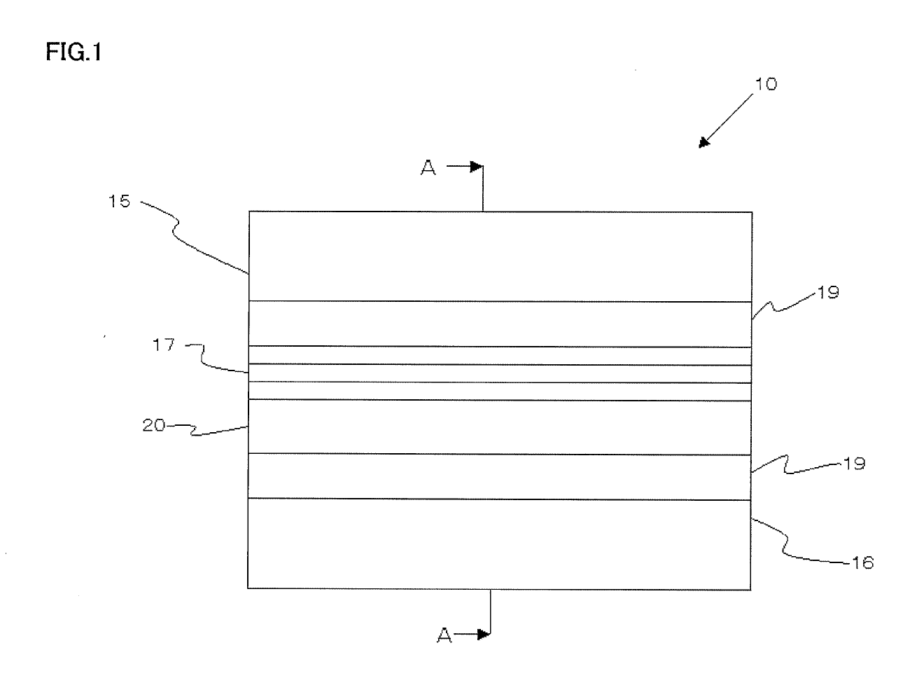

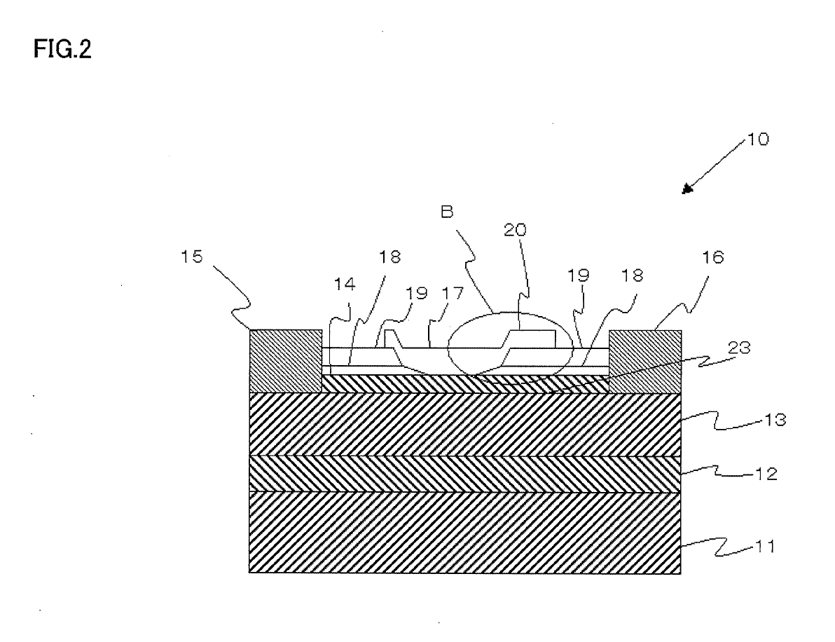

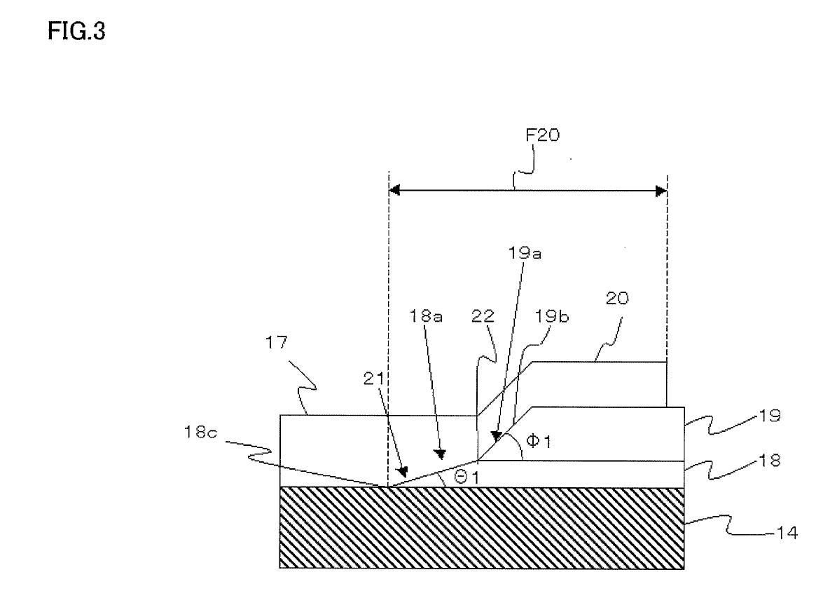

FIGS. 1 and 2 are respectively a schematic plan view and a schematic cross-sectional view taken along line A-A in FIG. 1 of the first embodiment of semiconductor device according to the present invention. FIG. 3 is an enlarged view of a part B of FIG. 2. The semiconductor device of this embodiment is a high electron mobility transistor (HEMT). The HEMT 10 includes a semiconductor layer formed on a substrate 11 and including a high resistance buffer layer 12, a channel layer (a carrier running layer) 13 and a barrier layer (a carrier supply layer) 14, a source electrode 15, a drain electrode 16, the source electrode 15 and the drain electrode 16 being so formed as to electrically contact a two-dimensional electron gas layer (which will be described in greater detail hereinafter), a gate electrode 17 formed between the source electrode 15 and the drain electrode 16 on the barrier layer 14, a cap layer 18 formed on the surface of the barrier layer 14 between the gate electrode 17 and the drain electrode 16 and between the gate electrode 17 and the source electrode 15, a passivation layer 19 covering the cap layer 18 and a field plate 20 for as part of the gate electrode 17 so as to cover an end of the cap layer 18 and part of the passivation layer 19. The cap layer 18 is made of a material having a composition containing part of the composition of the material of the barrier layer 14 and has a thickness of 2 to 50 nm. Two-dimensional electron gas (2 DEG) layer/channel 23 is formed between the buffer layer 13 and the barrier layer 14. The field plate 20 is within the range indicated by arrow F20 in FIG. 3 of the gate electrode 17.

In the HEMT 10 having the above configuration, preferably the end 21 of the cap layer 18 at the side of the gate electrode is provided with a taper angle θ₁ of not greater than 60° to form a slope 18a. The end 19a of the passivation layer 19 at the side of the gate electrode is provided with a taper angle φ₁ to form a slope 19b. With the above-described arrangement, the taper angle θ₁ formed at the end 21 of the cap layer 18 is smaller than the taper angle φ₁ formed at the end 19a of the passivation layer 19. Additionally, with the above-described arrangement, preferably the position of the top end of the slope 18a of the cap layer 18 agrees with the position of the bottom end of the slope 19b of the passivation layer 19 (at the spot indicated by reference symbol 22 in FIG. 3).

The substrate 11 may be made of silicon carbide, sapphire, spinel, ZnO, silicon, gallium nitride, aluminum nitride or some other material where nitride of a III group substance can grow.

The buffer layer 12 is produced on the substrate 11 to reduce the lattice mismatching, if any, between the substrate 11 and the channel layer 13. Preferably the buffer layer 12 has a film thickness of about 1,000 Å, although some other film thickness may alternatively be employed. A material suitable for the buffer layer 12 is AlₓGa₁₋ₓN (0≦x≦1). The buffer layer of this embodiment is made of GaN (AlₓGa₁₋ₓN, x=0).

The buffer layer 12 can be formed on the substrate 11 by means of a known semiconductor growth method such as a metal organic vapor phase epitaxial growth (MOVPE) process or a molecular beam epitaxial growth (MBE) process.

The HEMT 10 further includes a channel layer 13 formed on the buffer layer 12. An appropriate channel layer 13 can be made of nitride of a III group substance such as AlₓGa_{y}In_{(1-x-y)}N (0≦x≦1, 0≦y≦1, x+y≦1). In this embodiment, the channel layer 13 is a non-doped GaN layer having a film thickness of about 2 μm. The channel layer 13 can be formed on the buffer layer 12 by means of a known semiconductor growth method such as a metal organic vapor phase epitaxial growth (MOVPE) process or a molecular beam epitaxial growth (MBE) process.

In the HEMT 10, a barrier layer 14 is formed on the channel layer 13. The channel layer 13 can be made of nitride of a doped or undoped III group substance and so does the barrier layer 14. The barrier layer 14 is formed by one or more than one layers of different materials selected from InGaN, AlGaN, AlN, combinations of any of them and so on. In the embodiment, the barrier layer 14 is formed by a 0.8 nm-thick layer of AlN and a 22.5 nm-thick layer of AlₓGa₁₋ₓN. Two-dimensional electron gas (2DEG) layer/channel 23 is formed in the channel layer 13 near the hetero interface of the channel layer 13 and the barrier layer 14. Electrical isolation of devices is realized by mesa etching or ion injection outside the HEMT 10. The barrier layer 14 can be formed on the channel layer 13 by means of a known semiconductor growth method such as a metal organic vapor phase epitaxial growth (MOVPE) process or a molecular beam epitaxial growth (MBE) process.

Additionally, in the HEMT 10, a source electrode 15 and a drain electrode 16 are formed by using respective metals that are different from each other. Metal materials that can be used for them non-limitatively include alloys of titanium, aluminum, gold and nickel. The electrodes 15 and 16 are held in ohmic contact with the two-dimensional electron gas (2DEG) layer/channel 23. The layer formed by the cap layer 18 and the passivation layer 19 is formed between the source electrode 15 and the drain electrode 16 on the surface of the barrier layer 14. The cap layer 18 is made of a material of a composition containing part of the component of the material of the semiconductor layer and has a thickness of 2 to 50 nm. In other words, it is made of AlGaN, InGaN, GaN, AlN or the like. The cap layer 18 can be formed continuously on the barrier layer 14 by means of a known semiconductor growth method such as a metal organic vapor phase epitaxial growth (MOVPE) process or a molecular beam epitaxial growth (MBE) process.

To form the gate electrode 17, the cap layer 18 and the passivation layer 19 are dry-etched down to the barrier layer 14 and the metal to be used for the gate electrode 17 is deposited in such a way that the bottom surface of the gate electrode 17 is found on the barrier layer 14. Metal materials that can be used for the gate electrode 17 non-limitatively include gold, nickel, palladium, iridium, titanium, chromium, alloys of titanium and tungsten and platinum silicide.

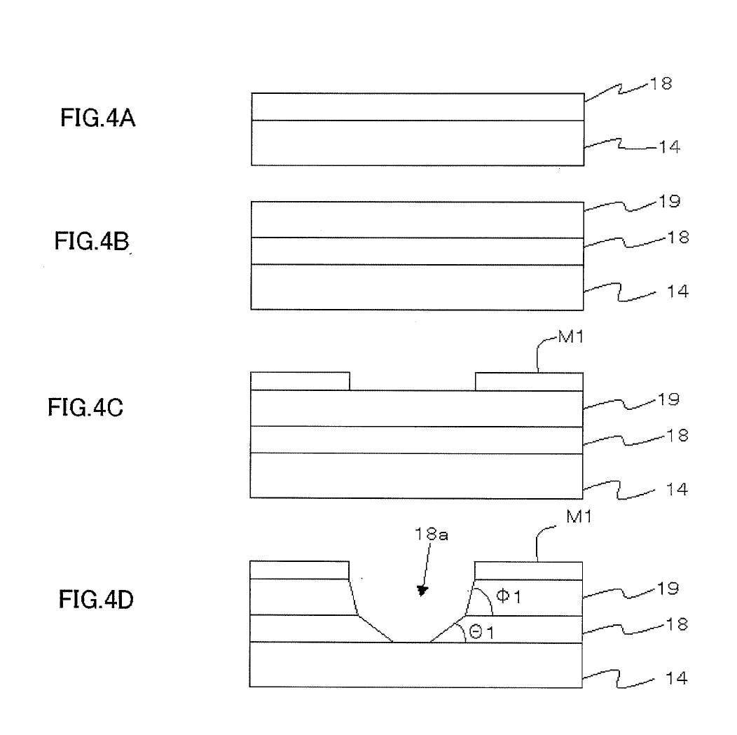

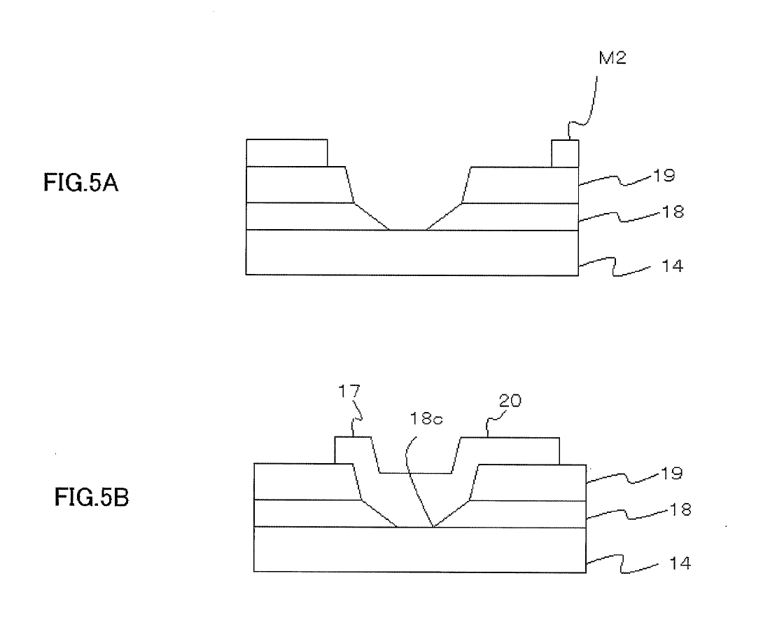

Now, the steps from the step of forming a cap layer 18 to the step of forming a field plate 20 will be described below by referring to FIGS. 4 and 5.

Firstly, a buffer layer 12, a channel layer (carrier running layer) 13, a barrier layer (carrier supply layer) 14 and a cap layer 18 are sequentially formed on a substrate by epitaxial growth (FIG. 4A). The barrier layer 14 and upper layers are shown in FIG. 4. Then, a passivation layer 19 is formed (FIG. 4B). The passivation layer 19 is a layer of a non-conductive material such as a dielectric (SiN or SiO). The passivation layer 19 may have a thickness selected from a number of different thicknesses and the appropriate range is between about 0.05 microns and 0.5 microns.

Then, a mask M1 is formed on the passivation film (FIG. 4C). The mask M1 may be a hard mask or a resist mask. The passivation layer 19 and the cap layer 18 are dry-etched by commonly using the mask M1 for them. The dry etching may be reactive ion etching. A gas seed that provides a strong anisotropy and makes the taper angle φ₁ at the lateral surface of the aperture large is employed for the passivation film while a gas seed that provides a strong isotropy and makes the taper angle θ₁ small is employed for the cap layer. Other etching conditions will also appropriately be selected. As a result, the angle θ₁ formed by the etched lateral wall surface of the cap layer 18 and the horizontal plane is made smaller than 90°, preferably smaller than 60°, to make the lateral wall surface a tapered and sloped surface (FIG. 4D). An aperture 18a is formed through the cap layer 18.

To form the field plate 20, a mask 20 is arranged so as to make the width of the aperture of the mask greater than the width of the aperture of the passivation layer 19 (FIG. 5A). Then, the electrode material is deposited on the entire surface by sputtering and both the electrode material on the mask and the mask are removed simultaneously by lift-off to form a gate electrode 17 having a field plate structure (FIG. 5B).

When the gate electrode 17 is biased to an appropriate level in the HEMT 10 that is formed in the above-described manner, an electric current can flow between the source electrode and the drain electrode by way of the two-dimensional electron gas (2DEG) layer/channel 23.

As described above, anisotropic etching of SiN or SiO is apt to take place at the time of dry etching the passivation layer 19 to make the taper angle φ₁ large and the taper angle θ₁ can be made smaller than the taper angle φ₁ of the passivation layer 19 because the cap layer 18 is made of gallium nitride or the like. Therefore, the taper angle θ₁ of the cap layer 18 is small at the angle section 18c of the gate electrode where an electric field is applied most strongly so that the electric field relaxation effect is enhanced.

To form the gate electrode 17 with the above-described method, a dry etching operation is conducted after forming a cap layer 18 and a passivation layer 19. Alternatively, a dry etching operation may be conducted after forming a cap layer 18 to deposit metal in the aperture and subsequently another dry etching operation may be conducted after forming a passivation layer 19. The latter method will be described below in terms of a modified example of the first embodiment.

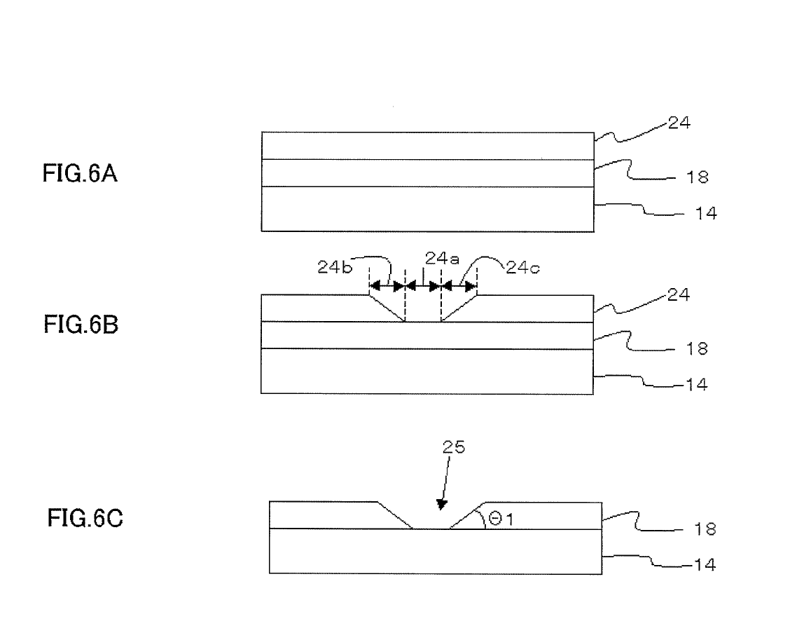

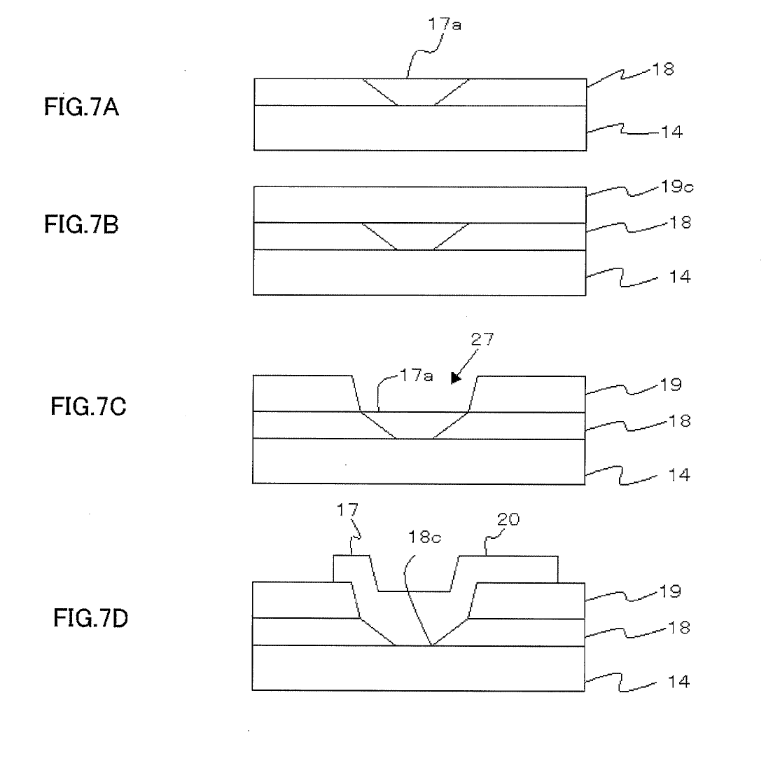

The steps from dry etching the cap layer 18 down to forming a field plate 20 will be described below in terms of a modified example of the first embodiment by referring to FIGS. 6 and 7.

A cap layer 18 can be dry-etched with a taper angle at an end thereof, which can be highly reproducibly formed by using a mask material and etching gas in a controlled manner. For example, photoresist 24 is applied onto a cap layer 18 which is a GaN layer to a uniform thickness (FIG. 6A). Then, the photoresist 24 is subjected to proximity exposure with a gap between the mask (mask pattern film) and the photoresist 24 held to about 10 to 20 μm. As a result, the photoresist 24 produces a completely exposed part, a completely unexposed part and a part where the extent of exposure gradually falls because of a diffraction phenomenon that arises between them. Thus, the exposed part of the photoresist 24 (the part indicated by arrow 24a in FIG. 6) can be completely eliminated when the photoresist 24 is developed, while the part of the photoresist 24 where the extent of exposure gradually falls (the part indicated by arrows 24b and 24c in FIG. 6) can partly be eliminated to show a tapered profile (FIG. 6B). After development, the exposed photoresist 24 is then rinsed for a predetermined time period and subjected to a post baking process for a predetermined time period.

Thereafter, the cap layer 18 is dry-etched by using the photoresist 24 that is made to show a tapered profile as mask. The dry etching may be reactive ion etching. As a result, the etched side wall surface of the cap layer 18 is made to show an angle θ₁ that is smaller than 90°, preferably smaller than 60°, relative to the horizontal plane (FIG. 6C). Then, an aperture 25 is formed in the cap layer 18.

The passivation layer 19 is a layer of a non-conductive material such as a dielectric (SiN or SiO). The passivation layer 19 may have a thickness selected from a number of different thicknesses and the appropriate range of thickness is between about 0.05 microns and 0.5 microns. For the passivation layer 19, metal to be used for the gate electrode 17a is deposited in the aperture 25 produced as a result of dry etching the cap layer 18 (FIG. 7A) and subsequently a non-conductive material 19c such as a dielectric (SiN or SiO) (a material from which the passivation layer 19 is formed) is deposited (FIG. 7B). Then an aperture 27 is formed in the non-conductive material 19c so as to expose the metal to be used for the gate electrode 17a to produce the passivation layer 19 (FIG. 7C).

The field plate 20 is formed on the passivation layer 19 from the aperture 27 so as to be joined to the metal to be used for the gate electrode 17a (FIG. 7D). The field plate 20 is made of a metal that is the same as the metal to be used for the gate electrode 17a. The gate electrode 17 is formed by the metal to be used for the gate electrode 17a and the field plate 20.

When the gate electrode 17 of the HEMT 10 formed in the above-described manner is biased to an appropriate level, an electric current can be made to flow between the source electrode and the drain electrode by way of the two-dimensional electron gas (2DEG) layer/channel 23.

Thus, with the modified example of the first embodiment, the taper angle φ₁ is relatively large because anisotropic etching is likely to occur when dry etching SiN or SiO for the passivation layer 19, whereas the taper angle θ₁ of the cap layer 18 can be made smaller than the taper angle φ₁ of the passivation layer 19 because gallium nitride or a similar material is employed for the cap layer 18. Therefore, the taper angle θ₁ of the cap layer 18 is small at the angle section 18c of the gate electrode where an electric field is applied most strongly so that the electric field relaxation effect is enhanced.

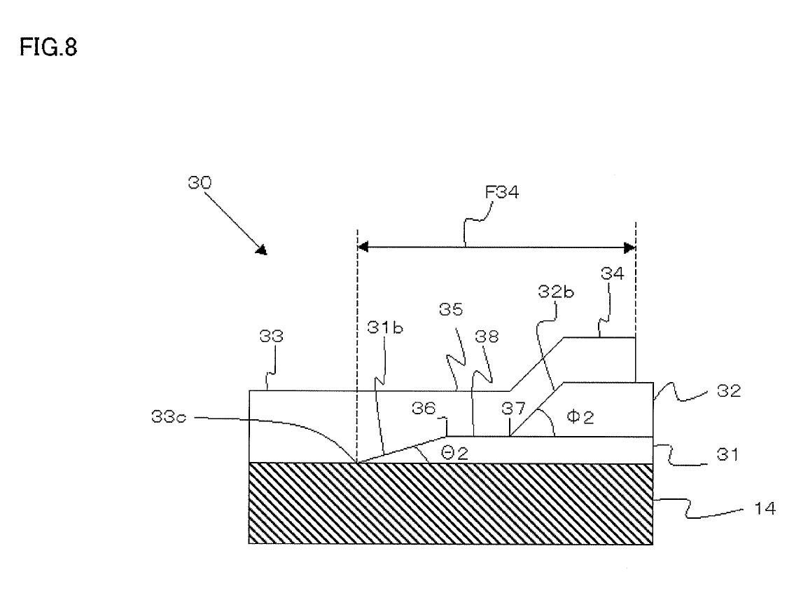

Now, the second embodiment of semiconductor device according to the present invention will be described below. Like the first embodiment, in the second embodiment, the end of the cap layer at the side of the gate electrode is provided with a taper angle θ₂ to form a slope. The end of the passivation layer at the side of the gate electrode is provided with a taper angle φ₂ to form a slope. The taper angle θ₂ formed at the end of the cap layer is smaller than the taper angle φ₂ formed at the end of the passivation layer. However, the second embodiment differs from the above-described first embodiment in that the position of the top end of the slope of the cap layer the position of the bottom end of the slope of the passivation layer differ from each other. This will be described by referring to FIG. 8, which is an enlarged view corresponding to FIG. 3 showing the first embodiment.

As shown in FIG. 8, a barrier layer 14, a cap layer 31, a passivation layer 32 and a gate electrode 33 having a field plate 34 are formed in a gate electrode section 30. The field plate 34 is within the range indicated by arrow F34 of the gate electrode 33. In the above-described arrangement, the position of the top end 36 of the end slope 31b of the cap layer 31 differs from the position of the bottom end 37 of the end slope 32b of the passivation layer 32. Therefore, a flat section 38 that contacts the gate electrode 33 is produced.

To form the gate electrode 17, the cap layer 18 and the passivation layer 19 are dry-etched down to the barrier layer 14 and the metal to be used for the gate electrode 17 is deposited in such a way that the bottom surface of the gate electrode 17 is found on the surface of the barrier layer 14. Metal materials that can be used for the gate electrode 17 non-limitatively include gold, nickel, palladium, iridium, titanium, chromium, alloys of titanium and tungsten and platinum silicide.

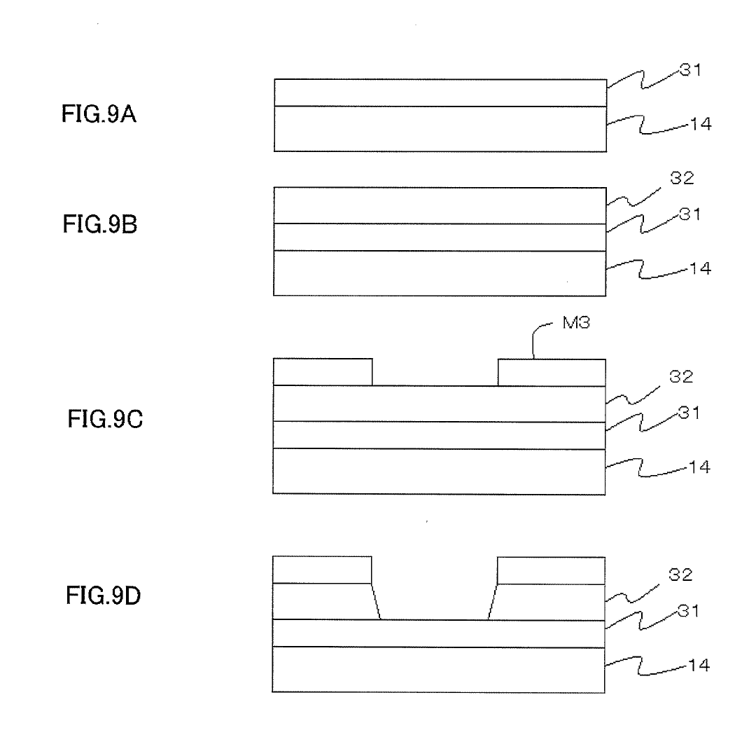

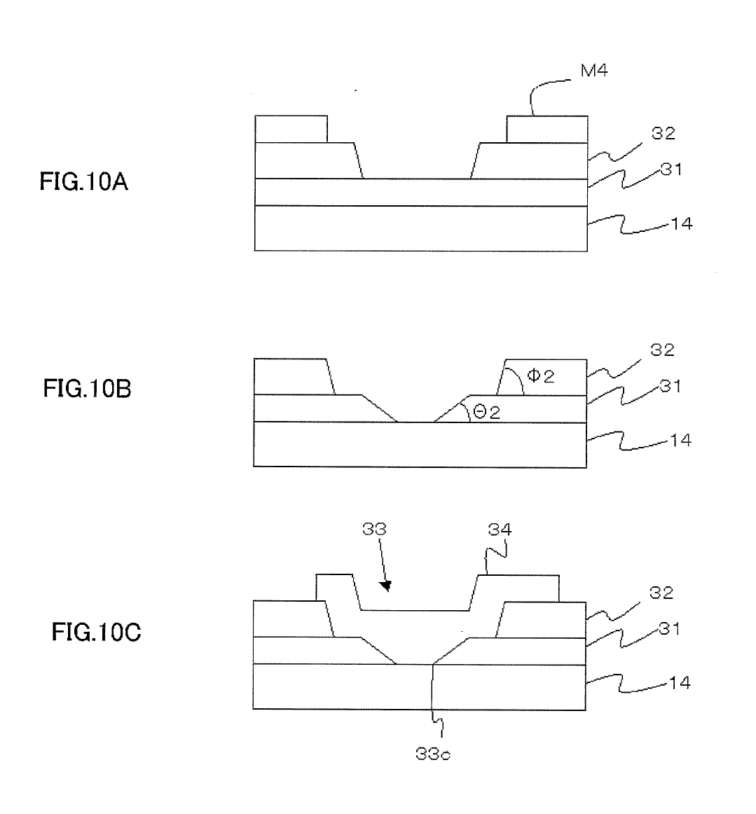

Now, the steps from the step of forming a cap layer 18 to the step of forming a field plate 20 will be described below by referring to FIGS. 9 and 10.

Firstly, a buffer layer 12, a channel layer (carrier running layer) 13, a barrier layer (carrier supply layer) 14 and a cap layer 31 are sequentially formed on a substrate by epitaxial growth (FIG. 9A). The barrier layer 14 and upper layers are shown in FIG. 9. Then, a passivation layer 32 is formed (FIG. 9B). The passivation layer 32 is a layer of a non-conductive material such as a dielectric (SiN or SiO). The passivation layer 32 may have a thickness selected from a number of different thicknesses and the appropriate range is between about 0.05 microns and 0.5 microns.

Then, a mask M3 is formed on the passivation layer 32 (FIG. 9C). The mask M3 may be a hard mask or a resist mask. The passivation layer 32 is dry-etched by using the mask M3. The dry etching may be reactive ion etching (FIG. 9D). A gas seed for etching that provides a strong anisotropy and makes the taper angle φ₂ large is employed for the passivation film while a gas seed for etching that provides a strong isotropy and makes the taper angle θ₂ small is employed for the cap layer. Other etching conditions are also appropriately selected. Subsequently, the mask is made to retreat (FIG. 10A) to broaden the width of the aperture and the passivation layer 32 and the cap layer 31 are etched. As a result, the angle θ₂ formed by the etched lateral wall surface of the cap layer 31 and the horizontal plane is made smaller than 90°, preferably smaller than 60°, to make the lateral wall surface a tapered and sloped surface (FIG. 10B). An aperture is formed through the cap layer 31.

To form the field plate 20, a mask is arranged so as to make the width of the aperture of the mask greater than the width of the aperture of the passivation film (FIG. 10C). Then, the electrode material is deposited on the entire surface by sputtering and both the electrode material on the mask and the mask are removed simultaneously by lift-off to form a gate electrode 17 having a field plate structure (FIG. 10C).

When the gate electrode 17 is biased to an appropriate level in the HEMT 10 that is formed in the above-described manner, an electric current can flow between the source electrode and the drain electrode by way of the two-dimensional electron gas (2DEG) layer/channel 23.

As described above, anisotropic etching of SiN or SiO is apt to take place to make the taper angle φ₂ large and the taper angle θ₂ can be made small because the cap layer 31 is made of gallium nitride. Therefore, the taper angle θ₂ of the cap layer 31 is small at the angle section 33c of the gate electrode 33 where an electric field is applied most strongly so that the electric field relaxation effect is enhanced. Note that the electric field relaxation effect is further enhanced because a flat section 38 that contacts the gate electrode is formed in the cap layer 31.

To form the gate electrode 17 with the above-described method, a dry etching operation is conducted after forming a cap layer and a passivation layer. Alternatively, a dry etching operation may be conducted after forming a cap layer to deposit metal in the aperture and subsequently another dry etching operation may be conducted after forming a passivation layer. The latter method will be described below in terms of a modified example of the second embodiment.

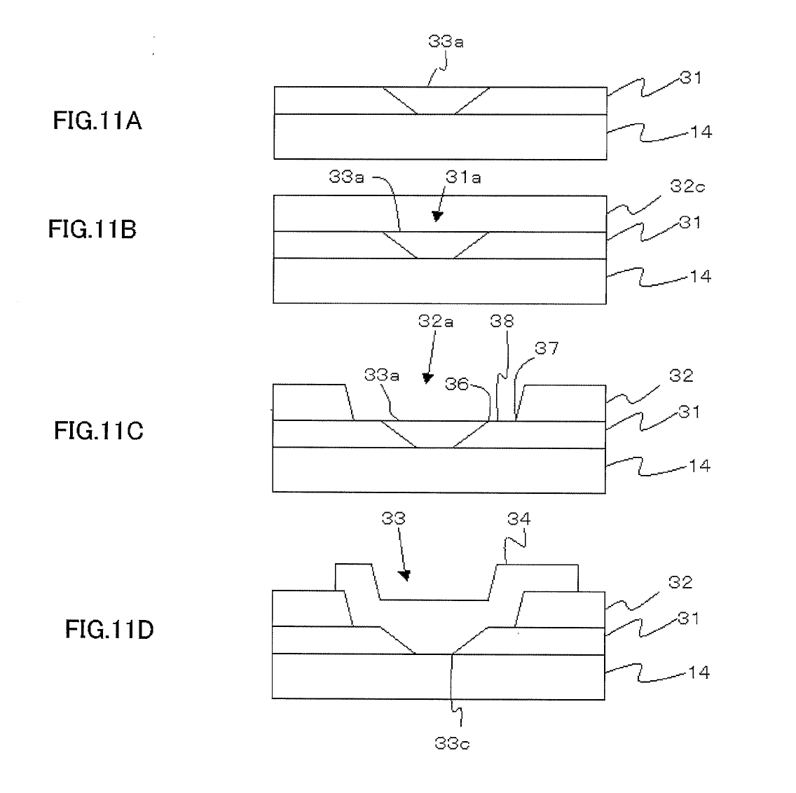

The steps from dry etching the cap layer 31 down to forming a field plate 34 will be described below in terms of a modified example of the second embodiment by referring to FIG. 11.

The cap layer 31 is dry-etched so as to form a taper by way of a process similar to the one described for the modified example of the first embodiment.

For the metal to be used for the gate electrode 33a, the cap layer 31 is dry-etched down to the barrier layer 14 and then the metal to be used for the gate electrode 33a is deposited in such a way that the bottom surface of the metal to be used for the gate electrode 33a is found on the surface of the barrier layer 14 (FIG. 11A).

The passivation layer 32 is a layer of a non-conductive material such as a dielectric (SiN or SiO). The passivation layer 32 may have a thickness selected from a number of different thicknesses and the appropriate range of thickness is between about 0.05 microns and 0.5 microns. For the passivation layer 32, metal to be used for the gate electrode 33a is deposited in the aperture 31a of the cap layer 31 (FIG. 11A) and subsequently a non-conductive material 32c such as a dielectric (SiO or SiN) (a material from which the passivation layer 32 is formed) is deposited (FIG. 11B). Then an aperture 32a that is broader than the top surface of the metal to be used for gate electrode 33a is formed by dry etching over a range broader than the top surface of the metal to be used for the gate electrode 33a so as to produce the passivation layer 32 (FIG. 11C). With this arrangement, the width of the aperture at the top surface of the cap layer 31 and the width of the aperture at the bottom surface of the passivation layer 32 differ from each other and hence the position of the top edge 36 of the edge slope of the cap layer 31 and the position of the bottom edge 37 of the edge slope of the passivation layer 32 differ from each other to produce a flat section 38 where the cap layer 31 contacts the gate electrode 33.

The field plate 34 is formed on the passivation layer 32 from the aperture 32a so as to be joined to the metal to be used for the gate electrode 33a (FIG. 11D). The field plate 34 is made of a metal that is the same as the metal to be used for the gate electrode.

When the gate electrode 33 of the HEMT 10 formed in the above-described manner is biased to an appropriate level, an electric current can be made to flow between the source electrode and the drain electrode by way of the two-dimensional electron gas (2DEG) layer/channel 23.

Thus, the taper angle φ₂ is relatively large because anisotropic etching is likely to occur when dry etching SiN or SiO, whereas the taper angle θ₂ of the cap layer can be made small because gallium nitride is employed for the cap layer. Therefore, the taper angle θ₂ of the cap layer 31 is small at the angle section 33c of the gate electrode 33 where an electric field is applied most strongly so that the electric field relaxation effect is enhanced. Note that the electric field relaxation effect is further enhanced because a flat section 38 that contacts the gate electrode is formed in the cap layer 31.

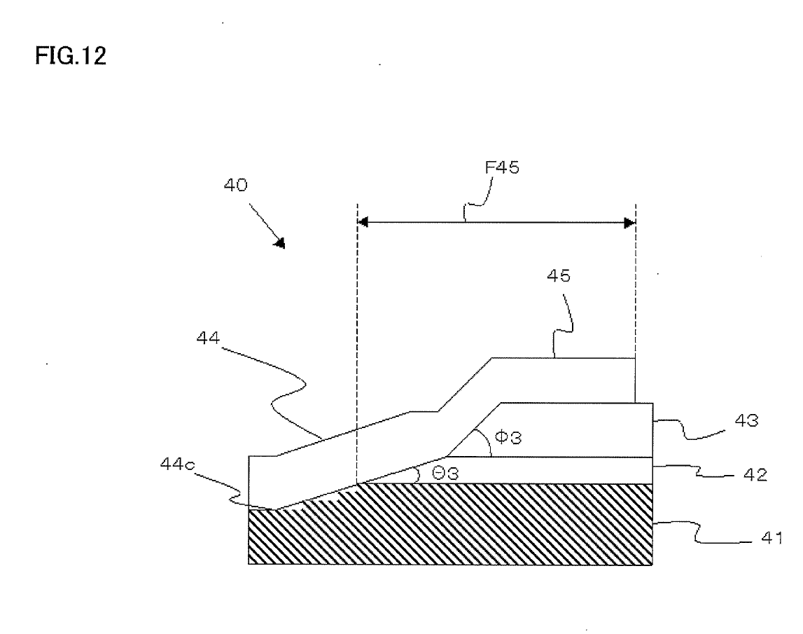

Now, the third embodiment of semiconductor device according to the present invention will be described below. The third embodiment is the same as the above-described first and second embodiments except that the gate electrode is arranged in the semiconductor layer that is partly recessed. This will be described by referring to FIG. 12, which is an enlarged view corresponding to FIG. 3 showing the first embodiment.

As shown in FIG. 12, a barrier layer 41, a cap layer 42, a passivation layer 43 and a gate electrode 44 having a field plate 45 are formed in a gate electrode section 40. The field plate 45 is within the range indicated by arrow F45 of the gate electrode 44. In the above-described arrangement, the gate electrode 44 is formed in the recess formed in the barrier layer 41.

To form the gate electrode 44, the cap layer 42 and the passivation layer 43 are dry-etched down to the inside of the barrier layer 41 and the metal to be used for the gate electrode 44 is deposited in such a way that the bottom surface of the gate electrode 44 is found in the inside of the barrier layer 41. Metal materials that can be used for the gate electrode 44 non-limitatively include gold, nickel, palladium, iridium, titanium, chromium, alloys of titanium and tungsten and platinum silicide.

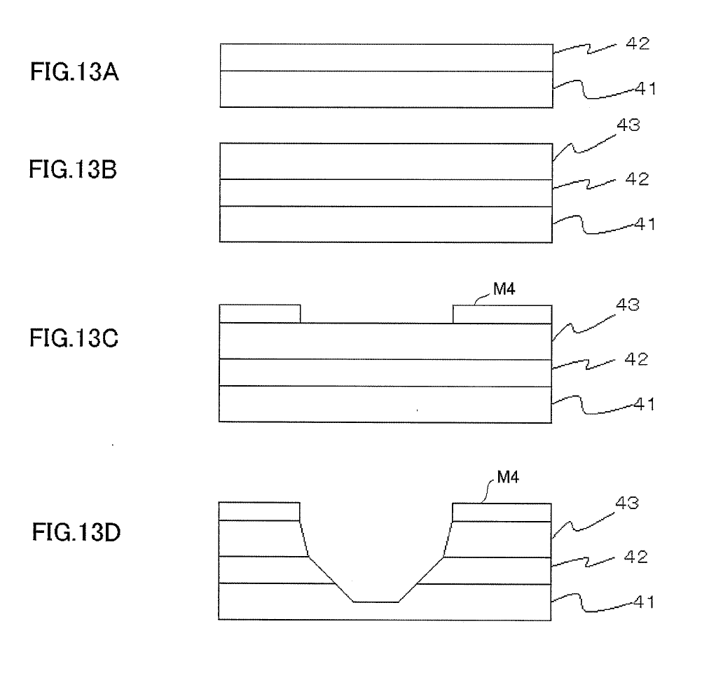

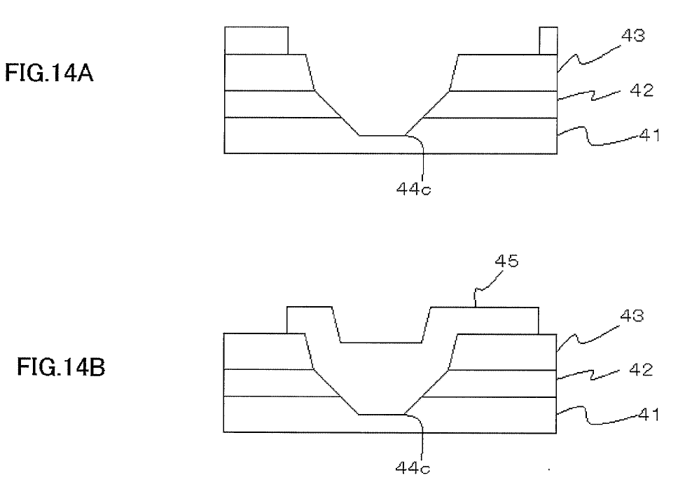

Now, the steps from the step of forming a cap layer 42 to the step of forming a field plate 45 will be described below by referring to FIGS. 13 and 14.

Firstly, a buffer layer, a channel layer (carrier running layer), a barrier layer (carrier supply layer) and a cap layer are sequentially formed on a substrate by epitaxial growth (FIG. 13A). The barrier layer and upper layers are shown in FIG. 13. Then, a passivation layer 43 is formed (FIG. 13B). The passivation layer 43 is a layer of a non-conductive material such as a dielectric (SiN or SiO). The passivation layer 43 may have a thickness selected from a number of different thicknesses and the appropriate range is between about 0.05 microns and 0.5 microns.

Then, a mask M4 is formed on the passivation film (FIG. 13C). The mask M4 may be a hard mask or a resist mask. The passivation film, the cap layer 42 and the barrier layer are dry-etched down to the inside of the barrier layer by commonly using the mask M4 for them. The dry etching may be reactive ion etching. A gas seed for etching that provides a strong anisotropy and makes the taper angle φ₃ large is employed for the passivation film while a gas seed for etching that provides a strong isotropy and makes the taper angle θ₃ small is employed for the cap layer. Other etching conditions are also appropriately selected. As a result, the angle θ₃ formed by the etched lateral wall surface of the cap layer 18 and the horizontal plane is made smaller than 90°, preferably smaller than 60°, to make the lateral wall surface a tapered and sloped surface (FIG. 13D). An aperture 25 is formed through the cap layer 18.

To form the field plate 20, a mask 20 is arranged so as to make the width of the aperture of the mask greater than the width of the aperture of the passivation film (FIG. 14A). Then, the electrode material is deposited on the entire surface by sputtering and both the electrode material on the mask and the mask are removed simultaneously by lift-off to form a gate electrode 17 having a field plate structure (FIG. 14B).

When the gate electrode 44 of the HEMT 10 formed in the above-described manner is biased to an appropriate level, an electric current can be made to flow between the source electrode and the drain electrode by way of the two-dimensional electron gas (2DEG) layer/channel 23.

Thus, the taper angle φ₃ is relatively large because anisotropic etching is likely to occur when dry etching SiN or SiO, whereas the taper angle θ₃ of the cap layer can be made small because gallium nitride is employed for the cap layer. Therefore, the taper angle of the cap layer 42 is small at the angle section 44c of the gate electrode 44 where an electric field is applied most strongly so that the electric field relaxation effect is enhanced. Note that both a large gain and excellent high frequency characteristics can be achieved because a recess gate structure is formed.

To form the gate electrode 17 with the above-described method, a dry etching operation is conducted after forming a cap layer and a passivation layer. Alternatively, a dry etching operation may be conducted after forming a cap layer to deposit metal in the aperture and subsequently another dry etching operation may be conducted after forming a passivation layer. The latter method will be described below in terms of a modified example of the third embodiment.

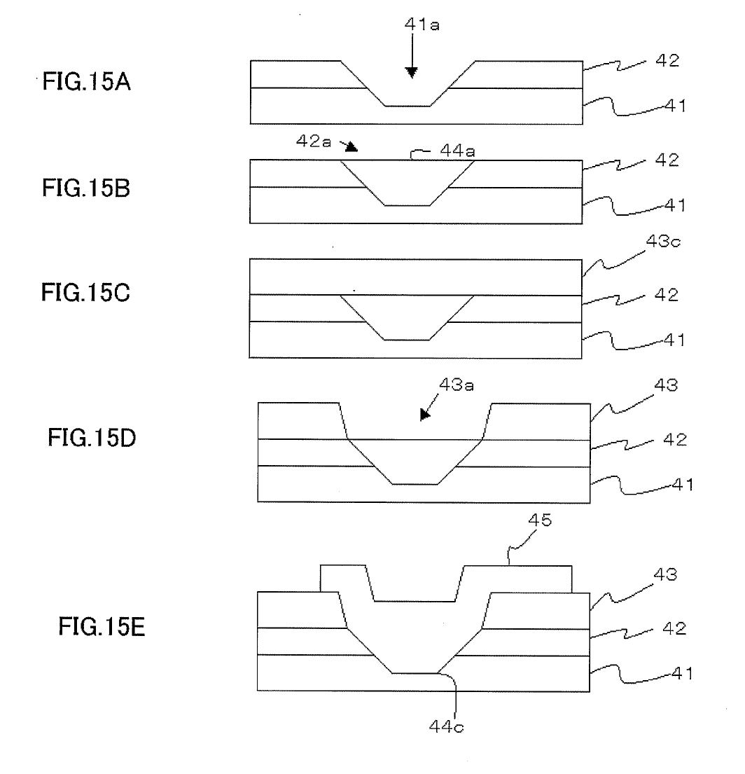

The steps from dry etching the cap layer 42 down to forming a field plate 45 will be described below in terms of a modified example of the third embodiment by referring to FIG. 15.

Firstly, the cap layer 42 is dry-etched and the barrier layer 41 is partly dry-etched to form a recess 41a in the barrier layer 41 (FIG. 15A). Then, the metal to be used for the gate electrode 44a is deposited in such a way that the bottom surface of the metal to be used for the gate electrode 44a is found in the recess 41a of the barrier layer 41 (FIG. 15B).

The cap layer 42 is dry-etched so as to form a taper by way of a process similar to the one described for the first embodiment. At this time, the dry etching is conducted down to the barrier layer 41.

The passivation layer 43 is a layer of a non-conductive material such as a dielectric (SiN or SiO). The passivation layer 43 may have a thickness selected from a number of different thicknesses and the appropriate range of thickness is between about 0.05 microns and 0.5 microns. For the passivation layer 43, metal to be used for the gate electrode 44a is deposited in the aperture 42a of the cap layer 42 (FIG. 15B) and subsequently a non-conductive material 43c such as a dielectric (SiN or SiO) (a material from which the passivation layer 43 is formed) is deposited (FIG. 15C). Then an aperture 43a is formed in the non-conductive material 43c so as to expose the metal to be used for the gate electrode 44a to produce the passivation layer 43 (FIG. 15D).

The field plate 45 is formed on the passivation layer 43 from the aperture 43a so as to be joined to the metal to be used for the gate electrode 44a by using the same metal (FIG. 15E).

When the gate electrode 44 of the HEMT 10 formed in the above-described manner is biased to an appropriate level, an electric current can be made to flow between the source electrode and the drain electrode by way of the two-dimensional electron gas (2DEG) layer/channel 23.

Thus, the taper angle φ₃ is relatively large because anisotropic etching is likely to occur when dry etching SiN or SiO, whereas the taper angle θ₃ of the cap layer can be made small because gallium nitride is employed for the cap layer. Therefore, the taper angle of the cap layer 42 is small at the angle section 44 of the gate electrode 44 where an electric field is applied most strongly so that the electric field relaxation effect is enhanced. Note that both a large gain and excellent high frequency characteristics can be achieved because a recess gate structure is formed.

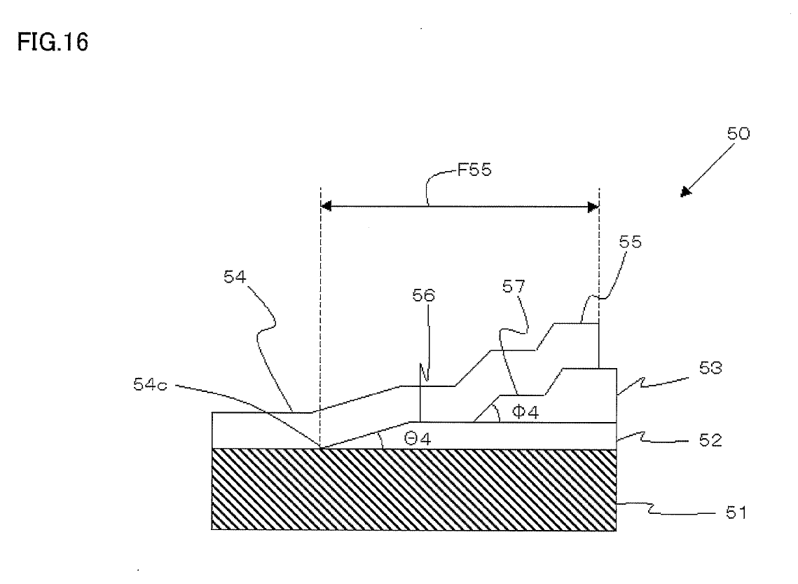

Now, the fourth embodiment of semiconductor device according to the present invention will be described below. The fourth embodiment is the same as the above-described first through third embodiments except that the passivation layer has a multi-step structure. This will be described by referring to FIG. 16, which is an enlarged view corresponding to FIG. 3 showing the first embodiment.

As shown in FIG. 16, a barrier layer 51, a cap layer 52, a passivation layer 53 and a gate electrode 54 having a field plate 55 are formed in a gate electrode section 50. The field plate 55 is within the range indicated by arrow F55 of the gate electrode 54. In the above-described arrangement, the passivation layer 53 has a multi-step structure. Therefore, a plurality of flat sections 56, 57 are produced and held in contact with the gate electrode.

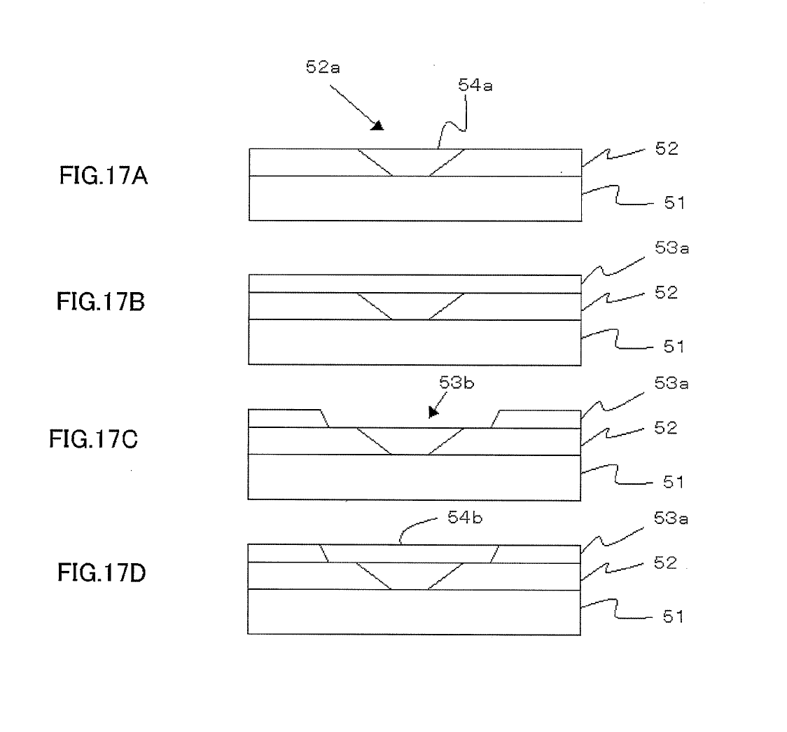

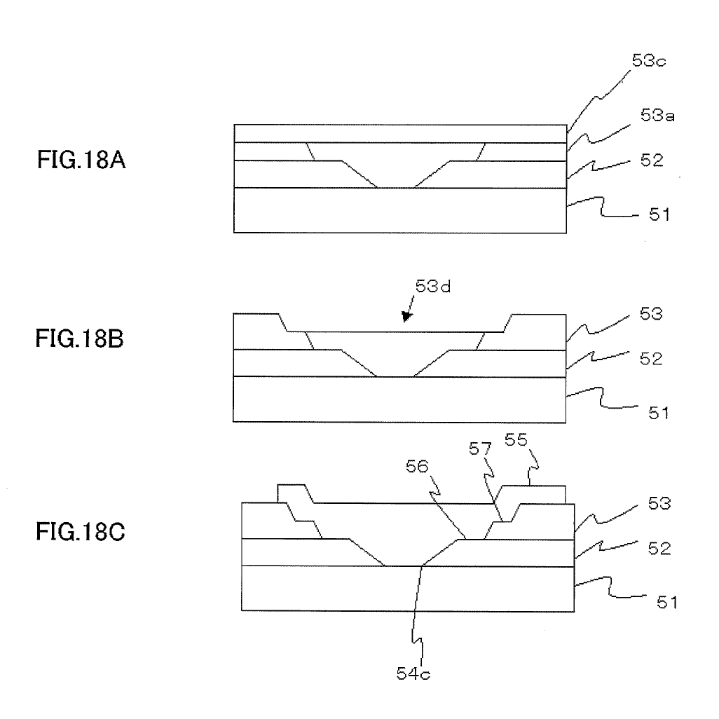

Now, the steps from dry etching the cap layer 52 down to forming a field plate 55 will be described below by referring to FIGS. 17 and 18.

Firstly, the cap layer 52 is dry-etched down to the barrier layer 51 and the metal to be used for the gate electrode 54a is deposited in such a way that the bottom surface of the metal to be used for the gate electrode 54a is found on the barrier layer 51.

The cap layer 52 is dry-etched so as to form a taper by way of a process similar to the one described for the first embodiment.

The passivation layer 53 is a layer of a non-conductive material such as a dielectric (SiN or SIC). The passivation layer 53 may have a thickness selected from a number of different thicknesses and the appropriate range of thickness is between about 0.05 microns and 0.5 microns. Firstly, for the first passivation layer 53a, metal to be used for the gate electrode 54a is deposited in the aperture 52a of the cap layer 52 (FIG. 17A) and subsequently a non-conductive material 53a such as a dielectric (SiN or SiO) (a material from which the passivation layer 53 is formed) is deposited (FIG. 17B). Then, an aperture 53b that is broader than the top surface of the metal to be used for gate electrode 54a is formed by dry etching over a range broader than the top surface of the metal to be used for the gate electrode 54a (FIG. 17C).

Metal 54b similar to the metal to be used for the gate electrode 54a is laid in the aperture 53b (FIG. 17D). Then, the non-conductive material (the material from which the passivation layer 53 is formed) 53c is laid again to a small thickness (FIG. 18A). Thereafter, a broad aperture 53d is formed to produce the passivation layer 53 (FIG. 18B). Then, metal similar to the metal to be used for the gate electrode 54a is deposited in the aperture 53d to finally form a field plate 55 (FIG. 18C). The field plate 55 is made of a metal that is the same as the metal to be used for the gate electrode 54a. As a result, a multi-step passivation layer where a plurality of flat sections 56, 57 are produced and held in contact with the gate electrode is formed.

When the gate electrode 54 of the HEMT 10 formed in the above-described manner is biased to an appropriate level, an electric current can be made to flow between the source electrode and the drain electrode by way of the two-dimensional electron gas (2DEG) layer/channel 23.

Thus, the taper angle φ₄ is relatively large because anisotropic etching is likely to occur when dry etching SiN or SiO, whereas the taper angle θ₄ of the cap layer 52 can be made small because gallium nitride is employed for the cap layer. Therefore, the taper angle of the cap layer 52 is small at the angle section 54c of the gate electrode 54 where an electric field is applied most strongly so that the electric field relaxation effect is enhanced. Note that the electric field relaxation effect is further enhanced because a plurality of flat sections including a flat section 56 and a flat section 57 that contact the gate electrode 54 are formed respectively in the cap layer 52 and in the passivation layer 53.

The cap layers 18, 31, 42 and 52 are made of GaN that is a non-doped insulating crystal in the above-described embodiments. However, the present invention is by no means limited thereto and an n-type semiconductor nitride or an amorphous nitride obtained by adding an impurity may alternatively be used for the cap layers. While the semiconductor devices of the above-described embodiments are HEMTs, the present invention is by no means limited thereto and may alternatively be field effect transistors (FETs).

The arrangement, the shape and the size of each of the above-described embodiments are described above only for a possible mode of carrying out the present invention. The numerical values and the compositions (materials) of the components are shown only as examples. Therefore, the present invention is by no means limited to the above-described embodiments, which may be modified and altered in various different ways without departing from the spirit and scope of the invention as defined in the appended claims.

A semiconductor device according to the present invention can find applications in the field of semiconductors to be used as high frequency and high withstand voltage power devices.

What is claimed is:

1. A semiconductor device comprising:
a substrate;
a nitride semiconductor layer formed on the substrate;
a source electrode formed so as to electrically contact with part of the nitride semiconductor layer;
a drain electrode formed so as to electrically contact with part of the nitride semiconductor layer;
a gate electrode formed between the source electrode and the drain electrode on the nitride semiconductor layer;
a cap layer formed between the gate electrode and the drain electrode on the surface of the nitride semiconductor layer;
a passivation layer covering the cap layer; and
a field plate formed as part of the gate electrode on the layer formed by the cap layer and the passivation layer;
the cap layer being made of a composition containing part of the composition of the material of the nitride semiconductor layer and having a thickness of 2 to 50 nm;
an end of the cap layer at the side of the gate electrode being provided with a taper angle of not greater than 60° to form a slope.

2. The semiconductor device according to claim 1, wherein
the taper angle of the end of the cap layer at the side of the gate electrode is smaller than the taper angle of the end of the passivation layer at the side of the gate electrode.

3. The semiconductor device according to claim 1, wherein
the end of the passivation layer at the side of the gate electrode is provided with a taper angle to form a slope; and
a position of a top end of the slope of the cap layer corresponds to the position of the bottom end of the slope of the passivation layer.

4. The semiconductor device according to claim 1, wherein:
the end of the passivation layer at the side of the gate electrode is provided with a taper angle to form a slope; and
the position of the top end of the slope of the cap layer differs from the position of the bottom end of the slope of the passivation layer.

5. The semiconductor device according to claims 1, wherein
a recess is formed in the surface of the nitride semiconductor layer and
the gate electrode is arranged in the recess.

6. The semiconductor device according to claims 1, wherein
the cap layer is made of a non-doped nitride semiconductor.

7. The semiconductor device according to claims 1, wherein
the cap layer is made of an n-type semiconductor.

8. The semiconductor device according to claims 1, wherein
the cap layer is made of an amorphous material.

9. The semiconductor device according to claims 1 and having a high electron mobility transistor (HEMT) structure, wherein
the nitride semiconductor layer includes at least a buffer layer on the substrate and a channel layer and a barrier layer formed on the buffer layer and two-dimensional electron gas is arranged in the channel layer.

10. The semiconductor device according to claim 9, wherein
the channel layer and the barrier layer are made of nitride of a III group substance such as AlₓGa_{y}In_{(1-x-y)}N (0≦x≦1, 0≦y≦1, x+y≦1).
